(19) United States
(12) Patent Application Publication
(10) Pub. No.: US 2015/0137313 A1
(43) Pub. Date: May 21, 2015

(54) Coil Arrangement with Metal Filling

(71) Applicant: Lantiq Deutschland GmbH, Neubiberg (DE)

(72) Inventors: Bernhard Tschuden, Villach (AT); Arnold Marak, Villach (AT)

(21) Appl. No.: 14/534,311

(22) Filed: Nov. 6, 2014

(30) Foreign Application Priority Data
Nov. 6, 2013 (DE) 10 2013 112 220.5

(51) Int. Cl. H01L 23/66; H01L 21/3205; C23C 16/50; H01L 49/02

(52) U.S. Cl. CPC H01L 23/66; H01L 28/10; H01L 21/32051; C23C 16/50; H01L 2223/6677
USPC 257/531; 438/3; 118/723 R

(57) ABSTRACT

Devices, methods and production devices that relate to the forming of a coil on a semiconductor substrate are provided. Arranged within the coil is a metal filling, for example with a density of less than 20%.

### TECHNICAL FIELD

The present application concerns for example coils formed on chips, in particular coils for radio-frequency applications.

Metal coils are designed for various purposes in the production of semiconductor components on chips, for example as radio-frequency coils (RF coils) for transmitting and/or receiving circuits, for example for wireless communication. Examples of wireless communication comprise WLAN, Bluetooth or communication via mobile radio networks. Coils are also required for other purposes, for example for transformers or baluns, also referred to in some applications as balance-to-unbalance transformers. Such coils are usually produced in a metallization process, in which a metal layer or typically a number of metal layers is/are applied to a semiconductor wafer or other substrate used for chip production. If the interior of the coil produced in this way remains free from metal, this may lead to problems in subsequent processes. On the other hand, a metal filling may impair the performance of the coil, for example in radio-frequency applications, due to the formation of eddy currents, for which reason metal fillings are not conventionally used.

### BRIEF DESCRIPTION OF THE DRAWINGS

Embodiments of the invention are explained in more detail with reference to the accompanying drawing, in which:

FIG. 1 shows a plan view of a device according to an embodiment,

FIG. 2 shows a block diagram of a manufacturing apparatus according to an embodiment,

FIG. 3 shows a flow diagram to illustrate a method according to an embodiment,

FIG. 4 shows a plan view of a metal layer of a chip according to an embodiment, and

FIG. 5 shows an illustrative example of metal patterns in various metal layers according to an embodiment.

### DETAILED DESCRIPTION

Various embodiments are explained in detail below. It should be noted that these embodiments merely serve for purposes of illustration and should not be interpreted as limiting the scope of the present application.

While for example embodiments with a number of features are presented, this should not be interpreted as meaning that all of these features are necessary for the implementation of embodiments. Rather, other embodiments may comprise fewer features than are presented and described, comprise alternative features and/or comprise additional features. Also, features of different embodiments may be combined with one another to form further embodiments. Modifications and variations that are described for one of the embodiments may also be applicable to other embodiments, as long as nothing to the contrary is indicated.

Various embodiments relate to metal fillings of coils which are formed on a substrate, for example a semiconductor substrate. In particular, such coils with a metal filling may be integrated together with other structures, for example circuits, on a chip. In some embodiments, the metal filling has a pattern of metallized regions in such a way that a metal density in one metal layer is less than 20%, for example between 10% and 15%. In some embodiments comprising a number of metal layers, the area density in each metal layer may be in a range of less than 20%, for example between 10% and 15%. Within the context of the present application, a density of a metal filling (e.g. metal layer) is understood as meaning the area density, i.e. a ratio of an area covered with metal to a total area of the metal filling. In this case, for example, a number of metal layers may be arranged one over the other, and metallized regions of the various metal layers may be arranged offset in relation to one another, so that metallizations (metallized areas) of different metal layers do not lie (directly) one over the other. Individual metallized regions of the pattern may for example have a size of between 0.5 μm·0.5 μm and 5 μm·5 μm and/or between 0.2 μm² and 10 μm², it being possible for the size and/or form also to differ according to the metal layer. The size of the individual metallized regions may for example be chosen on the basis of the so-called “Minimum Design Rule”, i.e. dependent from a minimal size allowed for a respective semiconductor process, in this case metallization process, for example in the range of 100%-200% of this size.

The metallized regions may be distributed uniformly in the metal filling, for example in the form of a uniform pattern, which in the case of some embodiments may facilitate subsequent processing.

Such metal fillings may be produced for example by plasma-based depositing processes. A metal filling with a low density such as this, e.g. of below 20% may for example also be referred to as a “plasma dust filling”.

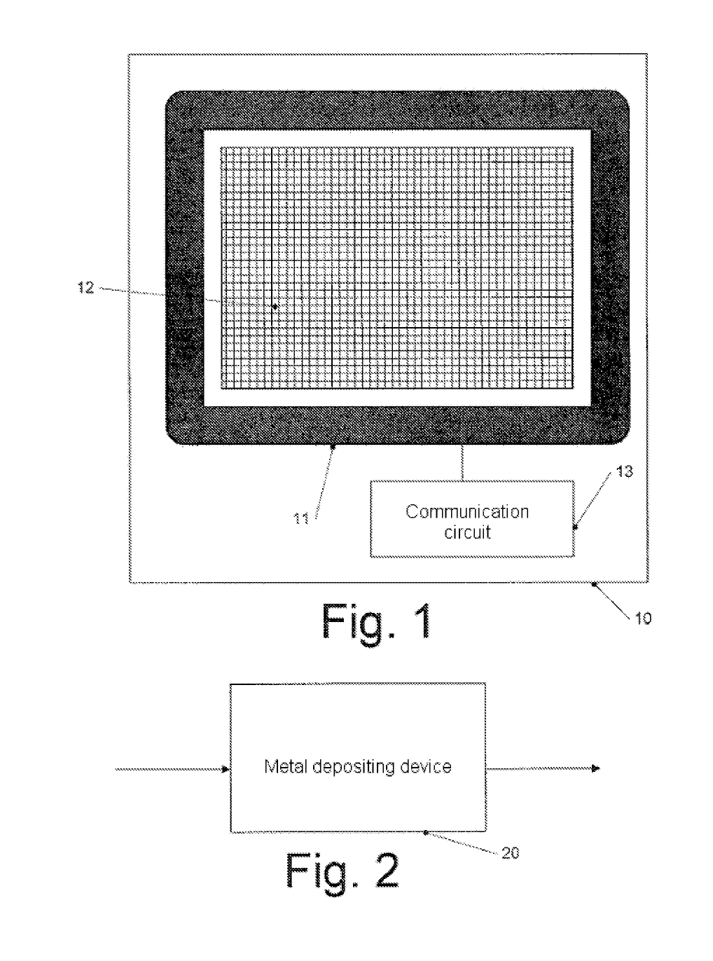

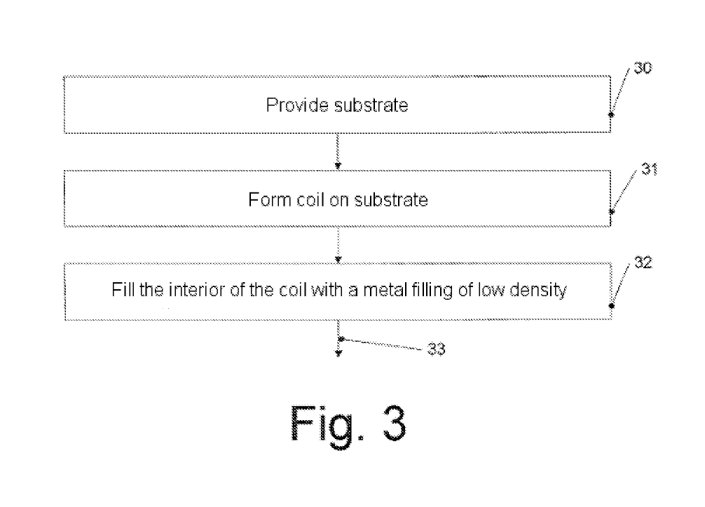

In FIG. 1, a schematic view of an embodiment is represented. It shows part of a substrate 10, for example a (possibly processed) semiconductor wafer, the part of the substrate 10 that is represented being able to form for example part of a chip after dicing. Formed on the substrate 10 by corresponding metal deposition is a coil 11, which may serve for example for transmitting and/or receiving of radio-frequency signals, for example for WLAN communication, Bluetooth communication or mobile radio communication, in a communication device. For this purpose, as an example, the coil 11 may be coupled with a corresponding communication circuit 13. In the case of the embodiment of FIG. 1, the communication circuit 13 is likewise formed on the substrate 10, so that the communication circuit 13 with the coil 11 can be formed in an integrated manner on a chip. In the case of other embodiments, the communication circuit 13 may also be formed entirely or partially on a substrate other than the substrate 10. However, the use of the coil 11 of FIG. 1 is not restricted to these cases. For example, the coil 11 may also be used in connection with circuits other than the communication circuit 13.

Arranged in the interior of the coil 11 is a metal filling 12. The metal filling 12 may for example comprise a metal layer or a plurality of metal layers, each metal layer having a pattern of metallized regions. The metallized regions may in this case be distributed uniformly or non-uniformly over the metal filling 12, so that a density of the metal filling for each layer is less than 20%, for example between 10 and 15%. As already mentioned, the size of the individual metallized regions may lie in a range between 0.5 μm·0.5 μm and 5 μm·5 μm, and for example be chosen dependently on a minimal size for a respective semiconductor design.

Such coils and metal fillings may for example be produced with a metal depositing device 20, shown schematically in FIG. 2 as a block diagram, for example a plasma device. As indicated by arrows, the metal depositing device 20 may be part of a semiconductor processing apparatus. Further devices may be provided upstream and downstream of metal depositing device 20, in order to carry out corresponding processing of substrates, for example in order to produce desired semiconductor components or devices.

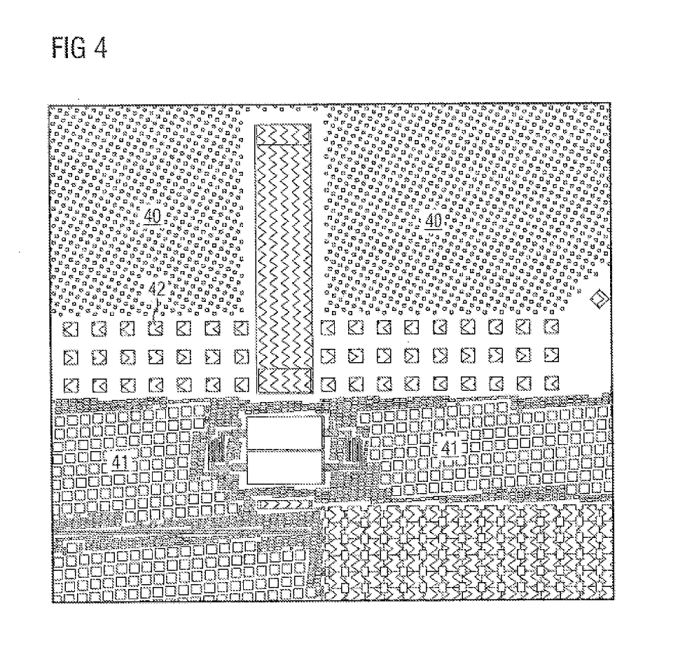

In FIG. 4, a representation of a metal layer of a chip according to an embodiment is shown. Elements of a coil are denoted by 42. In the interior of the coil, a metal filling 40 of low density, for example a density of less than 20%, for example between 10 and 15%, for example around 13.5%, is formed. Outside the coil, metal fillings 41 of higher density and further elements may be provided.

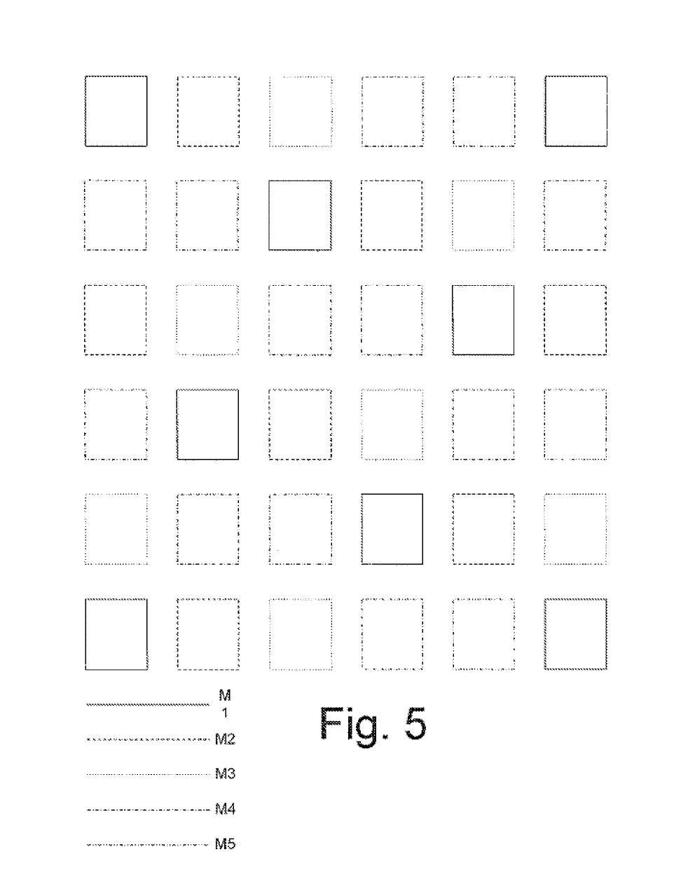

In FIG. 5, an example of a distribution of metallized regions for five metal levels M1-M5 according to an embodiment is represented, the various metal levels being illustrated by different types of lines, as can be seen in the legend of FIG. 5. The distances between the squares represented in FIG. 5 serve here merely for purposes of illustration and may also be omitted in an actual implementation. In an embodiment, each square in FIG. 5 corresponds to a possible location for a metallized region in a metal layer, a total of 36 of such locations being shown in a 6·6 pattern in FIG. 5 for purposes of illustration. In an embodiment, the area of the region represented in FIG. 5 may be 3.6 μm·3.6 μm, each square having a size of 0.6 μm·0.6 μm. This may be close to a minimally possible size of structures for a specific design, for example between 100% and 200% of this size.

For example, in an embodiment, the minimal area for a metallized region may be about 0.24 μm², in which case the example of 0.6 μm·0.6 μm would be about 50% above the minimal size. Even though square locations or metallized regions are shown in FIG. 5, other forms may be used in the case of other embodiments. For example, rectangular forms, angular forms other than with four corners, such as for example hexagons, or round forms may also be used. Each of the metal layers M1-M5 is assigned a number of possible locations for metallized regions, for example 7 or 8 regions, not all of these regions having to be metallized. The assignment of various possible locations to various metal layers achieves the effect that metallized regions of different metal layers do not overlap one another in such embodiments. For example, in the case of an embodiment, in each of the metal layers five of the regions assigned to the respective metal layer may actually be metallized, a different number of metallized regions also being possible.

Further metal layers may also be provided, layers for which for example different sizes of the metallized regions apply, for example on the basis of different possible minimal structure sizes of the processes used for the production of the metal layer. For example, in the case of a 6th metal layer, two metallized regions may be arranged in a region 3.6 μm·3.6 μm in size, each metallized region being able for example to have a size of 0.82 μm·0.82 μm, it being possible for a minimal area allowed by the design to be for example 0.565 μm² and a minimal length to be 0.4 μm. In a 7th metal layer, a metallized region of a size of 3 μm·3 μm may be arranged in a region of 9 μm·9 μm, where the size of 3 μm·3 μm may correspond to the minimally possible dimensions (Minimum Design Rule).

With metal fillings as described above in embodiments functioning and/or performance of the coil e.g. for radio-frequency applications is not, only slightly or only within acceptable limits adversely affected by the metal filling. On the other hand, subsequent processing may be improved.

It should be noted that all of the numerical values given above serve merely for purposes of illustration and, depending on the application, other numerical values may also be used. The arrangement of the metallized regions in FIG. 5 also merely serves as an example and other patterns and arrangements are also possible. Moreover, the metallized regions are not necessarily square, as represented in FIG. 5, but instead other forms are also possible.

The metallizations and the metallized regions may be produced by standard semiconductor processes, for example by plasma processes.

As is evident from the explanations above, the embodiments presented are merely intended for purposes of illustration and should not be interpreted as restrictive.

What is claimed is:

1. A device, comprising:
a semiconductor substrate,
a coil formed on the semiconductor substrate, and
a metal filling within the coil,
the coil being a radio-frequency coil of at least one of a radio-frequency transmitting, receiving or transceiver device.

2. The device according to claim 1, the at least one metal filling comprising a plurality of metal layers, a density in each of the plurality of metal layers being less than 20%.

3. The device according to claim 1, wherein a density of the metal filling is below 20%.

4. The device according to claim 2, metallized regions of one of the plurality of metal layers being arranged offset in relation to metallized regions of the others of the plurality of metal layers.

5. The device according to claim 2, wherein the density is between 10% and 15%.

6. The device according to claim 3, wherein the density is between 10% and 15%.

7. The device according to claim 1, the metal filling in at least one metal layer comprising a pattern of metallized regions.

8. The device according to claim 7, each metallized region of the pattern having a size of between 0.5 μm·0.5 μm and 5 μm·5 μm.

9. The device according to claim 7, each metallized region of the pattern having an area of between 100% and 200% of a minimally possible size for a semiconductor process used for the manufacturing of the respective metal layer.

10. The device according to claim 7, a size of the metallized regions of the pattern being between 0.2 μm² and 10 μm².

11. The device according to claim 1, the metal filling in at least one metal layer having a density of less than 20%.

12. The device according to claim 1, the coil being formed on a substrate coupled with a communication circuit.

13. A method, comprising:
forming a coil on a semiconductor substrate, the coil being a radio-frequency coil of at least one of a radio-frequency transmitting, receiving or transceiver device,
forming a metal filling within the coil.

14. The method according to claim 13, wherein forming the at least one metal filling comprises forming a plurality of metal layers, a density in each of the plurality of metal layers being less than 20%.

15. The method according to claim 13, wherein a density of the metal filling is below 20%.

16. The method according to claim 14, further comprising forming metallized regions of one of the plurality of metal layers offset in relation to metallized regions of the others of the plurality of metal layers.

17. The method according to claim 14, wherein the density is between 10% and 15%.

18. The method according to claim 13, wherein forming the metal filling in at least one metal layer comprises forming a pattern of metallized regions, a size of the metallized regions of the pattern being between 0.2 μm² and 10 μm².

19. An apparatus, comprising:
a metal depositing device, the metal depositing device being configured to form a coil and a metal filling within the coil on a semiconductor substrate, the coil being a coil of at least one of a radio-frequency transmitting, receiving or transceiver device.

20. The apparatus according to claim 19, the at least one metal filling comprising a plurality of metal layers, a density in each of the plurality of metal layers being less than 20%.
